(19) United States
(12) Patent Application Publication
(10) Pub. No.: US 2017/0303436 A1
(43) Pub. Date: Oct. 19, 2017

(54) HEAT EXCHANGE UNIT

(71) Applicant: HEATEX AB, Malmö (SE)

(72) Inventor: Gustav NYMAN, Nyköping (SE)

(21) Appl. No.: 15/514,054

(22) PCT Filed: Sep. 25, 2015
(86) PCT No.: PCT/EP2015/072183

§ 371 Date: Mar. 24, 2017

(30) Foreign Application Priority Data
Sep. 25, 2014 (EP) PCT/EP2014/070516

(51) Int. Cl. H05K 7/20; F28F 13/06; H05K 7/18

(52) U.S. Cl. CPC H05K 7/20536; H05K 7/20209; F28F 13/06; H05K 7/18

(57) ABSTRACT

A heat exchange unit (1) includes a heat exchange housing (3) and two heat exchange arrangements (4) located within the heat exchange housing (3). Each heat exchange arrangement (4) includes an outer (5a) and an inner (5b) air-to-air plate heat exchanger, which are connected in series. The heat exchange unit also relates to a totally enclosed electrical machine system with air to air cooling and a method for cooling the electrical machine system.

### FIELD

The aspects of the disclosed embodiments relate to a heat exchange unit comprising a heat exchange housing and heat exchangers connected in series. The aspects of the disclosed embodiments further relate to a totally enclosed electrical machine system using the mentioned heat exchange unit, and a method for cooling such an electrical machine system.

### BACKGROUND

Totally enclosed electrical machines, e.g. generators and motors, generate heat which will increase the temperature of the machine components and the air enclosed within the machine housing. As a result thereof, the electrical machine must be cooled to avoid overheating of components such as the stator, the rotor, or other electronic equipment.

Conventional methods of cooling a totally enclosed electrical machine comprise the use of either air-to-air heat exchangers or liquid-to-air heat exchangers. Air-to-air heat exchangers conventionally incorporate tubular heat exchangers, while liquid-to-air heat exchangers usually are of the fin-and-tube type.

Liquid-to-air heat exchangers are usually considered to be more efficient than tubular air-to-air heat exchangers, mainly due to the specific heat exchanger design. Tubular air-to-air systems are also, generally, heavier than liquid-to-air cooling systems.

However, tubular air-to-air heat exchangers have the advantages, compared to liquid-to-air heat exchangers, that there is no need for liquids such as water or refrigerants, the control system is less complex, fewer parts are required, and, generally, the cost is lower.

### SUMMARY

The aspects of the disclosed embodiments are directed to mitigating the above problems, and to provide efficient, non-complex, and light-weight cooling of electrical machines such as generators and motors.

According to a first aspect of the disclosed embodiments, a heat exchange unit comprises a heat exchange housing, two heat exchanger arrangements arranged within the heat exchange housing, each heat exchange arrangement comprising an outer and an inner air-to-air plate heat exchanger, said outer and inner heat exchangers being connected in series, and wherein air flow within each heat exchange arrangement may be deflected when flowing between the connected heat exchangers.

Such a heat exchange unit has high cooling performance, while at the same time having a non-complex design. Further, the invention comprises few parts, requires minimum maintenance, and has a lower overall cost. Also, it does not require the use of liquids. Having two heat exchangers arranged in series makes the heat exchange process more efficient compared to a conventional heat exchange arrangement with only one heat exchanger, and having two such heat exchanger arrangements within one heat exchange unit facilitates an even more efficient heat exchange process and yields an even temperature distribution on each side of an electrical machine which is to be cooled. Also, as a result of the air flow being deflected, the overall cooling of the electrical machine is further improved.

One side of the outer heat exchanger may comprise an external air inlet and one side of the inner heat exchanger may comprise an external air outlet. Further, the outer and inner heat exchangers may be arranged such that an external air outlet side of the inner heat exchanger is arranged at an angle in relation to an external air inlet side of the outer heat exchanger. The inner and outer heat exchangers are arranged at angles relative to each other in order to improve the overall cooling of the electrical machine, e.g. due to an increase in an opening area in the interface between the heat exchange unit and the electrical machine.

In one embodiment, the external air outlet side of the inner heat exchanger is arranged at a 45° angle in relation to the external air inlet side of the outer heat exchanger. This configuration allows for an improved overall cooling while at the same time keeping the width of the heat exchange unit as small as possible.

In another embodiment, the external air outlet side of the inner heat exchanger is arranged at a 90° angle in relation to the external air inlet side of the outer heat exchanger. This configuration allows for an improved overall cooling while at the same time keeping the height of the heat exchange unit as small as possible.

The heat exchange arrangements may be arranged within the heat exchange housing such that the external air inlet side of each outer heat exchanger may be located at one end of the heat exchange housing, respectively, and the external air outlet side of both inner heat exchangers may be located at a center section of the heat exchange housing. This allows for two separate external air circuits, facilitating an even more efficient heat exchange process when interacting with corresponding internal air circuits.

The outer and inner heat exchangers may be interconnected by means of an air deflection plate, being a simple and cost effective solution by which one avoids the need for separate ducts, connections, and other extra components for separating the external air circuits from corresponding internal air circuits.

The heat exchange unit may comprise at least one external air circuit fan in order to achieve the required air flow for the external air circuit.

According to a second aspect the disclosed embodiments include a totally enclosed electrical machine with air-to-air cooling, comprising the heat exchange unit as described above and an electrical machine unit, the heat exchange unit comprising a heat exchange housing and two heat exchange arrangements, each heat exchange arrangement comprising an outer and an inner air-to-air plate heat exchanger, the electrical machine unit comprising an electrical machine and an electrical machine housing, wherein one side of each outer heat exchanger comprises an internal air outlet and one side of each inner heat exchanger comprises an internal air inlet, each heat exchange arrangement being adapted for allowing external air to flow along an external air circuit extending from the exterior, through the outer heat exchanger and the inner heat exchanger, back to the exterior, and internal air to flow along an internal air circuit extending from the electrical machine unit, through the inner heat exchanger and the outer heat exchanger, back to the electrical machine unit, and wherein one external air circuit and one internal air circuit interact with each other across one heat exchanger arrangement, without mixing the air of the air circuits.

Such an electrical machine has high cooling performance, while at the same time having a non-complex design. Further, the solution comprises few parts, requires minimum maintenance, and has a lower overall cost. Also, it does not require the use of liquids.

In one embodiment, the electrical machine housing comprises a first end compartment, a middle compartment, and a second end compartment, and wherein each internal air circuit flows through two of the compartments and one heat exchange arrangement, respectively. Such an embodiment facilitates even cooling of the entire electrical machine.

The electrical machine may be a generator or a motor. According to a third aspect of the the disclosed embodiments include a method of cooling a totally enclosed electrical machine comprising a heat exchange unit and an electrical machine unit, wherein the heat exchange unit comprises first and second heat exchange arrangements and a heat exchange housing, and wherein the electrical machine unit comprises an electrical machine and an electrical machine housing, the method facilitating heat exchange in two simultaneous events between a first external air circuit and a first internal air circuit interacting across the first heat exchange arrangement, and a second external air circuit and a second internal air circuit interacting across the second heat exchange arrangement, without mixing the air of said air circuits, each external air circuit comprising the successive events of: external air entering an external air inlet arranged at one end of the heat exchange unit, the external air flowing through the heat exchange arrangement, the external air exiting an external air outlet arranged at a center top section of the heat exchange unit, each internal air circuit comprising the successive events of: internal air flowing at least partially through the electrical machine unit, the internal air exiting the electrical machine unit and entering an internal air inlet side of one of the heat exchange arrangements, the internal air flowing through the heat exchange arrangements, the internal air exiting an internal air outlet side of the heat exchange arrangement and re-entering the electrical machine unit.

As mentioned above, this solution has high cooling performance, while at the same time having a non-complex design. This solution also comprises few parts, requires low maintenance, and has a lower overall cost. Further, it does not require the use of liquids.

In one embodiment, the housing comprises first, middle, and second compartments, and the method further comprises that the internal air exits the electrical machine unit from the middle compartment, and that the internal air re-enters the electrical machine unit into the first or second compartment. Such an embodiment is normally adapted for generators provided with one internal air circuit fan, two internal air circuit fans, or no internal air circuit fan.

Generally, all terms used in the claims are to be interpreted according to their ordinary meaning in the technical field, unless explicitly defined otherwise herein. All references to “a/an/the [element, device, component, means, etc.]” are to be interpreted openly as referring to at least one instance of the element, device, component, means, etc., unless explicitly stated otherwise. Further, by the term “comprising” it is meant “comprising but not limited to” throughout the application.

### BRIEF DESCRIPTION OF THE DRAWINGS

This and other aspects of the present disclosure will now be described in more detail, with reference to the appended drawings showing currently preferred embodiments of the invention.

FIG. 1 shows a perspective view of an electrical machine provided with a heat exchange unit according to one embodiment, with only a section view of the front for the sake of clarity.

FIG. 2 shows a perspective view of an electrical machine system provided with a heat exchange unit according to another embodiment of the present invention, with only a section view of the front for the sake of clarity.

FIG. 3 shows a schematic view of the heat exchange unit according to the embodiment in FIG. 2.

FIG. 4 shows a perspective view of the electrical machine system in FIG. 1, including the front.

FIG. 5 shows a perspective view of the electrical machine system in FIG. 2, including the front.

### DETAILED DESCRIPTION

Electrical machines, e.g. generators and motors, generate undesirable heat, requiring the machine to be cooled. Totally enclosed electrical machine systems therefore usually include one or several heat exchangers of either the tubular, air-to-air type or the fin-and-tube, liquid-to-air type, used for dissipating the heat.

However, traditional cooling technology has several drawbacks. Tubular air-to-air heat exchangers are usually considered to be a low efficiency cooling system with large weight. The structural design of the tubular air-to-air heat exchanger usually comprises tubular heat exchanger elements extending from a drive end (DE) side to a non-drive end (NDE) side of the machine. Such a design, combined with an electrical machine utilizing two internal air circuits, leads to a decrease in efficiency and an uneven temperature difference between the DE and NDE sides. However, a liquid-to-air cooling system is usually designed with two heat exchangers, one for each side of the electrical machine, allowing two internal air circuits which results in symmetric cooling of the electrical machine. In other words, the two circuit cooling arrangement combined with the higher efficiency heat exchanger results in improved overall performance.

There is a need for a new cooling system which can maximize the overall heat dissipation, minimize the temperature difference between DE and NDE sides, and provide a mechanical design which promotes a lightweight, cost effective system using no liquids. Electrical motors are constantly improved and growing in both rated powers and physical size, and therefore there is a need for a more efficient cooling system for electrical machines.

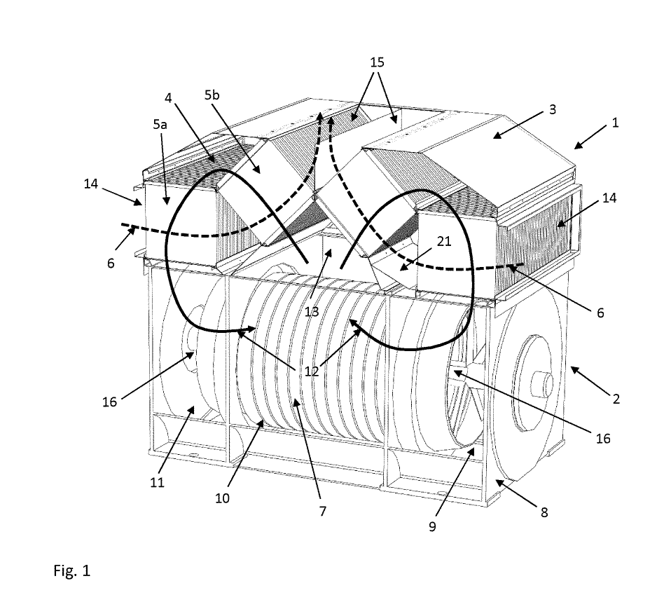

FIGS. 1, 2, 4, and 5 show a totally enclosed electrical machine including embodiments of a heat exchange unit 1 according to the present invention. The electrical machine comprises two main parts, i.e., a heat exchange unit 1 having air-to-air plate heat exchangers 5a, 5b, and an electrical machine unit 2. The electrical machine unit 2 comprises a housing 8 and an electrical machine 7 in the form of, preferably, either a generator or a motor. For the sake of simplicity and comprehension, the description below will refer to a generator throughout the text, but of course the generator could be replaced with a motor in all instances. By “totally enclosed” is meant that the external air circuits 6 are completely separated from the internal air circuits 12, as described in more detail below.

The heat exchange unit 1 comprises a heat exchange housing 3 which surrounds two heat exchange arrangements 4, arranged in parallel and symmetrically at each side, i.e. at opposite ends, of the heat exchange unit 1. Each heat exchange arrangement 4 comprises two heat exchangers 5a, 5b arranged in series. This allows for efficient and symmetric cooling of each side of the generator 7 due to the extension of the external and internal air circuits 6, 12, as described in more detail below.

The heat exchange unit 1 comprises two external air circuits 6, each flowing through one heat exchange arrangement 4, the heat exchange housing 3, and any suitable cover plates or partition plates within the unit 1. Each external air circuit 6 flows through only one heat exchange arrangement 4, i.e. through two heat exchangers 5a, 5b in series.

The heat exchange unit 1 may, if necessary, further comprise two external air inlets 14 and at least one external air outlet 15. The external air circuit 6 extends between one inlet 14 and one outlet 15, both connecting the external air circuit 6 with the exterior. By exterior is meant the exterior of the heat exchange unit 1, e.g., the outside of the heat exchange housing 3 or the open ambient air surrounding the electrical machine. The external air circuits 6 may be connected to the same outlet, e.g., the heat exchange unit 1 may have two separate inlets 14 but only one common outlet 15.

The inlets 14 and the outlet(s) 15 are arranged at any suitable location on the heat exchange housing 3 but preferably one inlet 14 is arranged on each side, i.e. at opposing ends, of the heat exchange housing 3 and one or two outlets 15 are arranged on top of the heat exchange housing 3. The outlet(s) 15 may also be arranged on the sides of the heat exchange housing 3.

Each inlet 14 and/or outlet 15 may be provided with, or connected to, at least one external air circuit fan, having either a push or pull configuration. It is understood that a push configuration means that the fan, delivering the air to the external circuit, is arranged before the external air enters the heat exchange unit 1, and a pull configuration means that the external air circuit fan is arranged after the external air exits the heat exchange unit 1. The fan may be integrated into the heat exchange housing 3 for both a push and a pull configuration. Also, the fan may be, if using a separate and free standing type of fan, connected to the heat exchange housing 3 by means of separate air ducts. The number and type of fans is easily adapted to specific needs. The external air circuit fan(s) may be connected to a control system, which is used for adjusting the fan speed, e.g., in response to the required cooling performance.

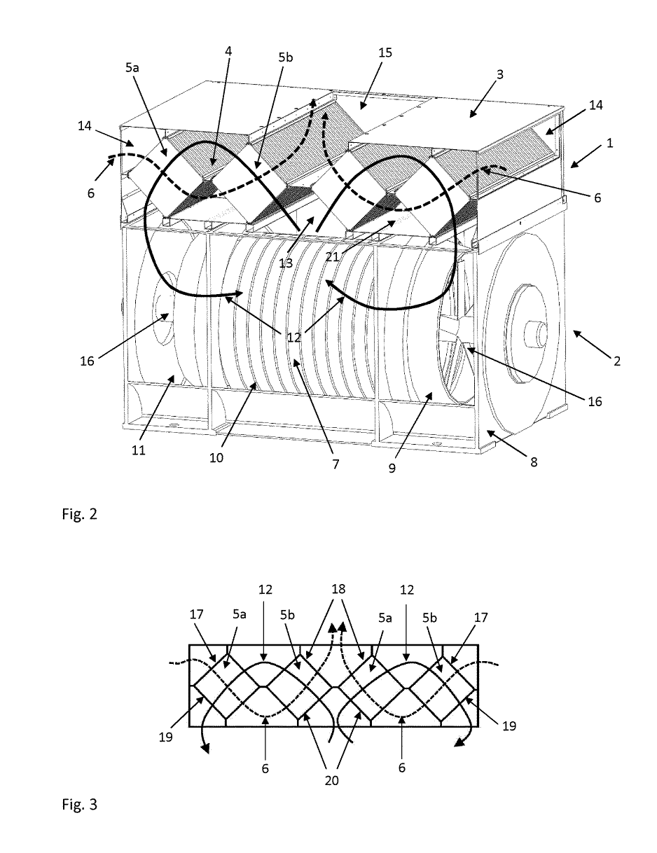

The electrical machine unit 2, shown in FIGS. 1 and 2 and referred to below as the generator unit, comprises an electrical machine housing 8, referred to below as generator housing, which surrounds an electrical machine, below referred to as the generator 7.

The generator housing 8 may comprise, in its interior, of three compartments arranged in series, below referred to as first end compartment 9, middle compartment 10, and second end compartment 11. The compartments are arranged in series after each other such that the end compartments 9, 11 are arranged on each side of the middle compartment 10. The use of “first” and “second” comprises no limitation in itself; it is merely used for facilitating understanding. The middle compartment 10 is, as already mentioned, arranged in-between the first end compartment 9 and second end compartment 11. The generator 7, or at least the generator shaft, extends through the compartments such that each end compartment 9, 11 comprises parts of the generator or one shaft end each. I.e., the generator 7 and/or its shaft extends from the first end compartment 9 to the second end compartment 11.

The generator unit 2 further comprises two internal air circuits 12, each being formed by the space present in-between the generator 7, the generator housing 8, the heat exchange arrangement 4, the heat exchange housing 3, and any other suitable cover plates or partition plates within the heat exchange unit 1 or the generator unit 2. The internal air circuits 12 are completely separated from the external air circuits 6.

The air in each internal air circuit 12 flows through only one end compartment 9, 11 and at least partially through the middle compartment 10, where after it flows through only one of the two heat exchange arrangements 4 in the heat exchange unit 1. In other words, the air flows through either the first end compartment 9 or the second end compartment 11, where after it enters the middle compartment 10. The air then exits the middle compartment 10 of the generator unit 2 and simultaneously enters the heat exchange unit 1. The air then flows through one of two heat exchanger arrangements 4, whereby heat is dissipated between the internal air circuit 12 and one corresponding external air circuit 6 flowing within each heat exchange arrangement 4, without mixing the air of the air circuits 6, 12. Subsequently, the air in the internal air circuit 12 exits the heat exchange unit 1 and simultaneously enters either the first end compartment 9 or the second end compartment 11 of the generator unit 2.

The use of two external and internal air circuits 6, 12 facilitates symmetric cooling of both sides of the generator unit (2), also referred to as the drive end (DE) side and the non-drive end (NDE) side, since one external and one internal air circuit 6, 12 cools only one half of the generator unit 2. Cooling using only one external air circuit 6 and one or two internal air circuit(s) 12 usually results in one end side of the generator unit 2 being somewhat warmer than the opposite end side, which can be harmful to the enclosed components. This is true no matter which type of air-to-air heat exchanger is being used.

FIGS. 1 and 2 also show two internal air circuit fans 16 arranged on the shaft of the generator 7, one fan being arranged in each end compartment 9, 11. When using two fans, the air flow may be directed in opposite directions. The fan may also be arranged at a location, within a compartment, other than directly on the generator shaft. However, it is not necessary that the generator is provided with fans on the internal air circuit at all, e.g. when the internal air flow is induced by the rotor part of the generator. This enables use of no fan, or, if the fan is arranged in the middle compartment 10, only one fan, for both internal air circuits 12 shown in FIGS. 1 and 2.

The heat exchange unit 1 and the generator unit 2 share a common interface 13. By interface is meant the connection between the heat exchange unit 1 and generator unit 2, i.e., the area between the heat exchange housing 3 and the generator housing 8, including the transition areas within compartments 9, 10, and 11.

The embodiments of the present invention may use cross flow plate heat exchangers, counter flow plate heat exchangers, or a combination of both cross flow and counter flow plate heat exchangers. Counter flow plate heat exchangers may be used either in series or in a single step design. Single step design means use of only one heat exchanger per heat exchanger arrangement.

The present invention comprises two preferred embodiments of the heat exchange unit 1, as shown by FIGS. 1-3.

Both embodiments of the heat exchange unit 1 comprise a heat exchange housing 3 within which two heat exchange arrangements 4 are located. Each heat exchange arrangement 4 comprises two air-to-air plate heat exchangers, i.e., an outer 5a and an inner 5b heat exchanger connected in series. The heat exchangers are essentially rectangular cuboids , i.e., the plates of each heat exchanger are preferably square in shape, while the heat exchanger may have any suitable dimensions in the direction perpendicular to the plane of the plates. The terms “outer” and “inner” are merely used to distinguish the heat exchangers 5a, 5b from each other. The outer heat exchangers 5a are arranged adjacent opposing ends of the heat exchange housing 3, i.e., the outer heat exchangers 5a are arranged adjacent one external air inlet 14 each. The inner heat exchangers 5b are preferably arranged at a center section of the heat exchange housing 3, adjacent each other and the external air outlet(s) 15.

The air flow within each heat exchange arrangement 4, i.e., the air flowing through the external air circuits 6 and the internal air circuits 12, is deflected when flowing between each pair of series connected heat exchangers 5a, 5b. One side 17 of each outer heat exchanger 5a comprises an external air inlet and one side 18 of each inner heat exchanger 5b comprises an external air outlet. I.e., the external air inlet side 17 of the outer heat exchanger 5a is arranged adjacent the external air inlet 14 arranged at one end of the heat exchange housing 3, and the external air outlet side 18 of the inner heat exchanger 5b is arranged adjacent the external air outlet(s) 15 arranged approximately at the center section of the heat exchange housing 3.

Correspondingly, one side 19 of each outer heat exchanger 5a comprises an internal air outlet and one side 20 of each inner heat exchanger 5b comprises an internal air inlet. I.e., the internal air outlet side 19 of the outer heat exchanger 5a is arranged at one end of the heat exchange housing 3, and the internal air inlet side 20 of the inner heat exchanger 5b is arranged approximately at the center section of the heat exchange housing 3

In order to provide the above mentioned deflection of air, the outer and inner heat exchangers 5a, 5b are arranged such that the external air outlet side 18 of the inner heat exchanger 5b is arranged at an angle in relation to the external air inlet side 17 of the outer heat exchanger 5a. Correspondingly, the internal air outlet side 19 of the inner heat exchanger 5b is arranged at an angle in relation to the internal air inlet side 20 of the outer heat exchanger 5a.

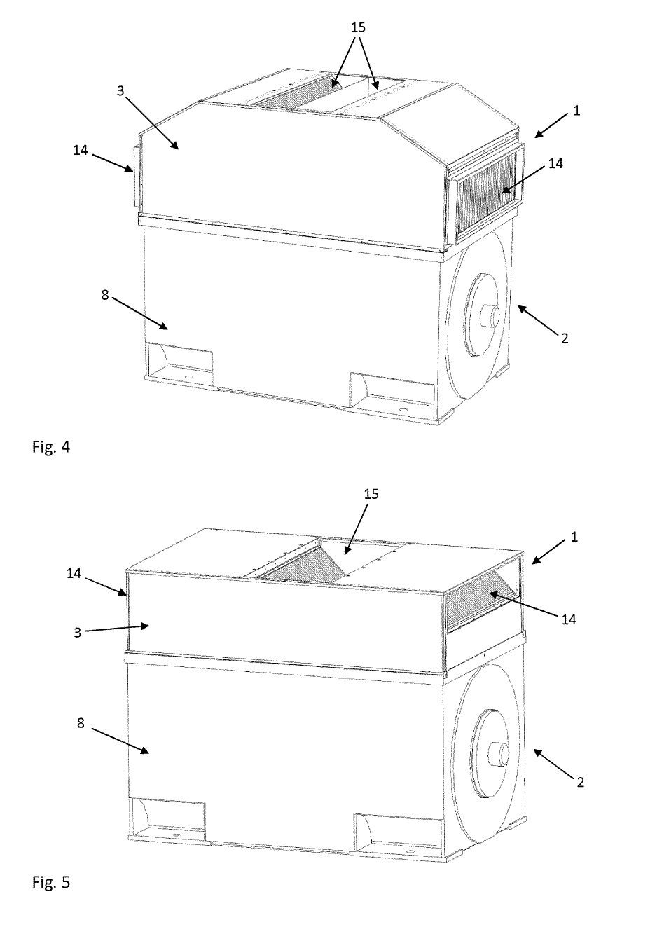

In the embodiment shown in FIGS. 1 and 4, the external air outlet side 18 of the inner heat exchanger 5b is arranged at a 45° angle in relation to the external air inlet side 17 of the outer heat exchanger 5a. In other words, the outer heat exchanger 5a is arranged such that the external air circuit 6 flows in a direction parallel to the generator shaft, and the inner heat exchanger 5b is arranged such that the external air circuit 6 flows at an angle relative to the direction of the generator shaft. The inner heat exchangers 5b, in FIG. 1, are tilted approximately 45° in relation to the outer heat exchangers 5a, such that one diagonal of the square plates extends in a direction parallel to the generator shaft. Such a solution facilitates easy drainage of any water, which may have accidentally entered the heat exchanger arrangement 4, hence avoiding water stagnating inside the unit. This also allows for a heat exchange unit having an as small width as possible, the width being the dimension extending in a direction parallel to the generator shaft.

In the embodiment shown in FIGS. 2, 3, and 5, the external air outlet side 18 of the inner heat exchanger 5b is arranged at a 90° angle in relation to the external air inlet side 17 of the outer heat exchanger 5a. In other words, both the outer and the inner heat exchangers 5a, 5b are arranged such that the external air circuit 6 flows at an angle relative to the direction of the generator shaft. This means that all heat exchangers 5a, 5b are arranged such that one diagonal of the square plates extends in a direction parallel to the generator shaft. This also allows for a heat exchange unit having an as small height as possible, the height being the dimension extending perpendicular to a direction parallel to the generator shaft and parallel to the plane of the plates.

Tilting the inner heat exchangers 5b by 45° or 90°, in relation to the direction of the generator shaft, will increase the open area from which the internal air circuits 12 will exit the interface 13 of the generator unit 2 and enter the heat exchange unit 1, thereby leading to a more evenly distributed air flow over the generator unit. Also, it will yield a smoother path for the external air circuits 6, leading to lower pressure losses and more even velocity profiles which improves the cooling performance of the heat exchange unit 1.I.e., when the inner heat exchangers 5b are angled, the interface 13 opening area between heat exchange unit 1 and the middle compartment 10 of the generator unit 2 is increased, which improves the air flow, and the air flow is more evenly distributed between the middle compartment 10 of the generator housing 3 and the heat exchange unit 1.

In both embodiments, each set of series connected outer and inner heat exchangers 5a, 5b may be arranged in abutment along one longitudinal edge, and interconnected by means of at least one air deflection plate 21 along an adjacent longitudinal edge. Longitudinal, in this case, meaning the direction perpendicular to the plane of the heat exchanger plates. In other words, the air deflection plate 21 is preferably mounted between one edge of an external air outlet side of the outer heat exchanger 5a and one edge of an external air inlet side of the inner heat exchanger 5b, i.e., the air deflection plate 21 extends between the outer and inner heat exchangers 5a, 5b.

The air deflection plate 21 acts as an air flow deflection plate for both the external and internal air circuits 6, 12.

As previously mentioned, at least one external air circuit fan may be arranged on a center top section of the heat exchange housing 3, over the external air outlet(s) 15 and therefore in connection with the external air outlet sides 18 of the two inner heat exchangers 5b.

As shown in FIGS. 1, 2, 4, and 5, the heat exchange unit 1 is preferably mounted on top of the generator unit 2, however, those skilled in the art understands that the heat exchanger unit 1 also could be mounted below, or on the side of, the generator unit 2.

Each heat exchange arrangement 4 is adapted for allowing external air to flow along the external air circuit 6 which extends from the exterior, firstly through the outer heat exchanger 5a and thereafter through the inner heat exchanger 5b, and back to the exterior, and for allowing internal air to flow along the internal air circuit 12 which is a closed loop extending from the generator unit 2, firstly through the inner heat exchanger 5b and thereafter through the outer heat exchanger 5a, where after it returns back to the generator unit 2. I.e., only one external air circuit 6 and one internal air circuit 12 interact within one heat exchanger arrangement 4.

As previously mentioned, the generator housing 8 may be divided into a first end compartment 9, a middle compartment 10, and a second end compartment 11. In such an embodiment, each internal air circuit 12 flows through only two of the compartments, either first end compartment 9 and middle compartment 10, or second end compartment 11 and middle compartment 10, and through one heat exchange arrangement 4.

In conclusion, heat exchange within a generator system comprising the above discussed heat exchange unit 1 and generator unit 2 is facilitated by means of two simultaneous events occurring between a first external air circuit 6 and a first internal air circuit 12 interacting across a first heat exchange arrangement 4, and a second external air circuit 6 and a second internal air circuit 12 interacting across a second heat exchange arrangement 4. The terms “first” and “second” are used to separate the two heat exchange arrangements 4 and accompanying air circuits 6, 12 from each other within the generator system.

Each external air circuit 6 comprises the successive events of external air entering the external air inlet 14 arranged at one end of the heat exchange unit 1, the external air flowing through the heat exchange arrangement 4, and the external air exiting the external air outlet 15 arranged at the center top section of the heat exchange unit 1.

Each internal air circuit 12 comprises the successive events of internal air flowing through the generator unit 2, the internal air exiting the generator unit 2 and entering the internal air inlet side 20 of one heat exchange arrangement 4, the internal air flowing through the heat exchange arrangements 4, and the internal air exiting the internal air outlet side 19 of the heat exchange arrangement 4 and re-entering the generator unit 2.

As previously mentioned, the generator housing 8 may comprise first end 9, middle 10, and second end 11 compartments. In this embodiment, each internal air circuit 12 will exit the generator unit 2 from the middle compartment 10, and re-enter the generator unit 2 through either the first 9 or the second 11 end compartment.

As described above, FIGS. 1 and 2 show two different embodiments of a heat exchange unit according to the present invention. FIG. 1 shows a heat exchange unit wherein the inlet and outlet sides of connected heat exchangers are arranged at a 45° angle relative each other, while FIG. 2 shows a heat exchange unit wherein the inlet and outlet sides of connected heat exchangers are arranged at a 90° angle relative each other. The person skilled in the art realizes that the present invention by no means is limited to the preferred embodiments described above. On the contrary, many modifications and variations are possible within the scope of the appended claims. For example, the heat exchange unit 1 may be arranged on any suitable electrical machine. Also, the inlet and outlet sides of connected heat exchangers may be arranged at different angles towards each other.

1. A heat exchange unit (1) comprising a heat exchange housing (3), two heat exchange arrangements (4) arranged within said heat exchange housing (3), each heat exchange arrangement (4) comprising an outer (5a) and an inner (5b) air-to-air plate heat exchanger, said outer and inner heat exchangers (5a, 5b) being connected in series, and wherein air flow (6, 12) within each heat exchange arrangement (4) is deflected when flowing between said connected heat exchangers (5a, 5b).

2. A heat exchange unit (1) according to claim 1, wherein one side (17) of said outer heat exchanger (5a) comprises an external air inlet and one side (18) of said inner heat exchanger (5b) comprises an external air outlet.

3. A heat exchange unit (1) according to claim 2, wherein said outer and inner heat exchangers (5a, 5b) are arranged such that an external air outlet side (18) of said inner heat exchanger (5b) is arranged at an angle in relation to an external air inlet side (17) of said outer heat exchanger (5a).

4. A heat exchange unit (1) according to claim 3, wherein said external air outlet side (18) of said inner heat exchanger (5b) is arranged at a 45° angle in relation to said external air inlet side (17) of said outer heat exchanger (5a).

5. A heat exchange unit (1) according to claim 3, wherein said external air outlet side (18) of said inner heat exchanger (5b) is arranged at a 90° angle in relation to said external air inlet side (17) of said outer heat exchanger (5a).

6. A heat exchange unit (1) according claim. 24, wherein said heat exchange arrangements (4) are arranged within said heat exchange housing (3) such that said external air inlet side (17) of each outer heat exchanger (5a) is located at one end of said heat exchange housing (3), respectively, and said external air outlet side (18) of both inner heat exchangers (5b) is located at a center section of said heat exchange housing (3).

7. A heat exchange unit (1) according to claim 1, wherein said outer and inner heat exchangers (5a, 5b) are interconnected by means of an air deflection plate (21).

8. A heat exchange unit (1) according to claim 1, wherein said heat exchange unit (1) comprises at least one external air circuit fan.

9. A totally enclosed electrical machine system with air-to-air cooling, comprising the heat exchange unit (1) according to claim 1 and an electrical machine unit (2),
said heat exchange unit (1) comprising a heat exchange housing (3) and two heat exchange arrangements (4), each heat exchange arrangement (4) comprising an outer (5a) and an inner (5b) air-to-air plate heat exchanger,
said electrical machine unit (2) comprising an electrical machine (7) and an electrical machine housing (8),
wherein one side (19) of each outer heat exchanger (5a) comprises an internal air outlet and one side (20) of each inner heat exchanger (5b) comprises an internal air inlet, each heat exchange arrangement (4) being adapted for allowing
external air to flow along an external air circuit (6) extending from the exterior, through said outer heat exchanger (5a) and said inner heat exchanger (5b), back to the exterior, and
internal air to flow along an internal air circuit (12) extending from said electrical machine unit (2), through said inner heat exchanger (5b) and said outer heat exchanger (5a), back to said electrical machine unit (2),
and wherein one external air circuit (6) and one internal air circuit (12) interact with each other across one heat exchanger arrangement (4) without mixing the air of said air circuits (6, 12).

10. A totally enclosed electrical machine system according to claim 9, wherein said electrical machine housing (8) comprises a first end compartment (9), a middle compartment (10), and a second end (11) compartment, and wherein each internal air circuit (12) flows through two of said compartments (9 and 10; 11 and 10) and one heat exchange arrangement (4), respectively.

11. A totally enclosed electrical machine system according to claim 9, wherein said electrical machine (7) is a generator or a motor.

12. Method of cooling a totally enclosed electrical machine system comprising a heat exchange unit (1) and an electrical machine unit (2), wherein said heat exchange unit (1) comprises first and second heat exchange arrangements (4) and a heat exchange housing (3), and wherein said electrical machine unit (2) comprises an electrical machine (7) and an electrical machine housing (8),
said method facilitating heat exchange in two simultaneous events between a first external air circuit (6) and a first internal air circuit (12) interacting across said first heat exchange arrangement (4), and a second external air circuit (6) and a second internal air circuit (12) interacting across said second heat exchange arrangement (4), without mixing the air of said air circuits (6, 12),
each external air circuit (6) comprising the successive events of:
external air entering an external air inlet (14) arranged at one end of said heat exchange unit (1), said external air flowing through said heat exchange arrangement (4), said external air exiting an external air outlet (15) arranged at a center top section of said heat exchange unit (1),
each internal air circuit (12) comprising the successive events of:
internal air flowing at least partially through said electrical machine unit (2), said internal air exiting said electrical machine unit (2) and entering an internal air inlet side (20) of one of said heat exchange arrangements (4), said internal air flowing through said heat exchange arrangements (4), said internal air exiting an internal air outlet side (19) of said heat exchange arrangement (4) and re-entering said electrical machine unit (2).

13. Method of cooling a totally enclosed electrical machine system according to claim 12, wherein said housing (8) comprises first, middle, and second compartments (9, 10, 11), and said method further comprises that
said internal air exits said electrical machine unit (2) from said middle compartment (10), and that said internal air re-enters said electrical machine unit (2) into said first or second compartment (9, 11).
